(19) United States
(12) Patent Application Publication
(10) Pub. No.: US 2017/0358358 A1
(43) Pub. Date: Dec. 14, 2017

(54) FLASH MEMORY

(71) Applicant: Renesas Electronics Corporation, Tokyo (JP)

(72) Inventor: KOICHI ANDO, Tokyo (JP)

(73) Assignee: Renesas Electronics Corporation, Tokyo (JP)

(21) Appl. No.: 15/585,871

(22) Filed: May 3, 2017

(30) Foreign Application Priority Data
Jun. 14, 2016 (JP) 2016-117618

(51) Int. Cl. G11C 16/10; G11C 16/04; G11C 16/14

(52) U.S. Cl. CPC G11C 16/10; G11C 16/14; G11C 16/0466

(57) ABSTRACT

Retention characteristics after rewriting can be improved.

A flash memory includes a plurality of sectors each of which includes a plurality of memory cells. In a case in which a fluctuation range of a threshold voltage in a memory cell on which a write operation is performed is greater than a fluctuation range of a threshold voltage in a memory cell on which an erase operation is performed, after one sector is used, when another sector is used, a write operation is performed on all the memory cells of the one sector.

### CROSS-REFERENCE TO RELATED APPLICATIONS

The disclosure of Japanese Patent Application No. 2016-117618 filed on Jun. 14, 2016 including the specification, drawings and abstract is incorporated herein by reference in its entirety.

### BACKGROUND

The present invention relates to a flash memory.

In recent years, flash memory is used for, for example, USB memories and memory cards, and can easily store electronic data generated by a personal computer, a digital camera, and the like. Further, for example, as described in Japanese Unexamined Patent Application Publication No. Hei 11(1999)-134317, the flash memory is mounted in a microcomputer and used for storing information handled by the microcomputer. Besides the above uses, the flash memory is used for various uses.

### SUMMARY

In a flash memory having a MONOS (metal-oxide-nitride-oxide-silicon) type memory cell, electrons are injected into a nitride film in a write operation and holes are injected into the nitride film in an erase operation. However, when rewriting is repeated many times, charges that cannot be removed by the rewriting begin to be segregated locally in the nitride film as mismatch charges. In a state in which there are such mismatch charges, if information is coded by the rewriting and thereafter the coded information is left as it is in a high temperature state or for a long time, these charges are recombined and eliminated by an internal electric field between electrons and holes and thermal diffusion. Then, a threshold voltage of the memory cell fluctuates largely, so that retention characteristics (data holding characteristics) are degraded.

Therefore, an object of the present invention is to improve the retention characteristics after the rewriting. Other objects and novel features will become apparent from the description of the present specification and the accompanying drawings.

A flash memory according to a typical embodiment includes a plurality of sectors, each of which includes a plurality of memory cells. In a case in which a fluctuation range of a threshold voltage in a memory cell on which a write operation is performed is greater than a fluctuation range of a threshold voltage in a memory cell on which an erase operation is performed, after one sector is used, when another sector is used, a write operation is performed on all the memory cells of the one sector.

The following explains briefly the effect obtained by the typical invention among the inventions disclosed in the present application.

According to the typical embodiment, it is possible to improve the retention characteristics after the rewriting.

### BRIEF DESCRIPTION OF THE DRAWINGS

FIG. 1 is a block diagram showing an example of a configuration of a flash memory according to a first embodiment of the present invention.

FIG. 2 is a diagram showing an example of a configuration of a memory array according to the first embodiment of the present invention.

FIG. 3 is a diagram showing an example of the memory array according to the first embodiment of the present invention.

FIG. 4 is a diagram schematically showing a cross-sectional structure of a memory cell according to the first embodiment of the present invention.

FIG. 5 is a diagram showing an example of a voltage applied to the memory cell according to the first embodiment of the present invention.

FIG. 6 is a flowchart showing an example of a method of using the flash memory according to the first embodiment of the present invention.

FIGS. 7A and 7B are diagrams showing a usage state of the memory array according to the first embodiment of the present invention.

FIGS. 8A, 8B, 8C and 8D are diagrams showing a usage state of the memory array according to the first embodiment of the present invention.

FIG. 9 is a diagram schematically showing a process in which mismatch charges disappear in the first embodiment of the present invention.

FIGS. 10A and 10B are diagrams schematically showing fluctuations of threshold voltages in the memory cell according to the first embodiment of the present invention.

FIG. 11 is a flowchart showing an example of a method of using a flash memory according to a second embodiment of the present invention.

FIGS. 12A and 12B are diagrams showing a usage state of a memory array according to the second embodiment of the present invention.

FIGS. 13A, 13B, 13C and 13D are diagrams showing a usage state of the memory array according to the second embodiment of the present invention.

FIGS. 14A and 14B are diagrams schematically showing fluctuations of threshold voltages in a memory cell according to the second embodiment of the present invention.

FIG. 15 is a diagram showing retention characteristics in a related art flash memory.

FIG. 16 is a flowchart showing an example of a method of using the related art flash memory.

FIGS. 17A and 17B are diagrams showing a usage state of a memory array in the related art flash memory.

FIGS. 18A, 18B, 18C and 18D are diagrams showing a usage state of the memory array in the related art flash memory.

FIG. 19 is a diagram schematically showing mismatch charges in the related art flash memory.

FIG. 20 is a diagram showing retention characteristics in the related art flash memory.

### DETAILED DESCRIPTION

Hereinafter, embodiments of the present invention will be described in detail with reference to the drawings. In all the drawings for describing the embodiments, the same components are denoted by the same reference numerals in principle and repeated description thereof will be omitted.

### First Embodiment

### [Configuration of Flash Memory]

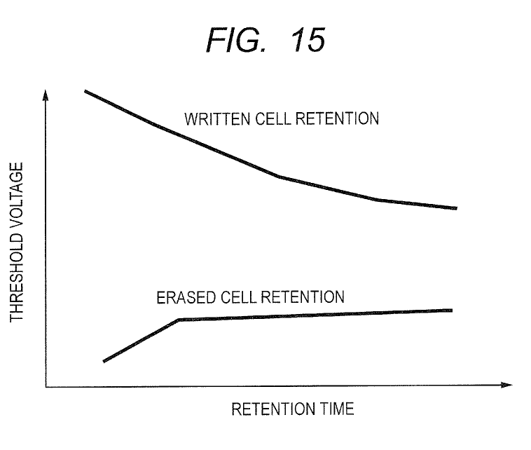

In the present embodiment, a case in which the mismatch charge is a hole will be described. FIG. 15 is a diagram showing retention characteristics in a related art flash memory. In a memory cell (a written cell) in which a write operation is performed during rewriting, holes which are mismatch charges recombine with electrons which are injected by the write operation, so that as shown in FIG. 15, a threshold voltage in the memory cell fluctuates (drops) largely. Therefore, in the written cell, the retention characteristics degrade. On the other hand, in a memory cell (an erased cell) in which a write operation is not performed during rewriting, holes which are mismatch charges coexist with holes which are injected by the most recent erase operation and the holes and electrons rarely recombine with each other, so that the threshold voltage in the memory cell hardly fluctuates. Therefore, in the erased cell, the degradation of the retention characteristics is suppressed. In other words, when the mismatch charges are holes, a fluctuation range of the threshold voltage in the memory cell on which the write operation is performed is greater than a fluctuation range of the threshold voltage in the memory cell on which the erase operation is performed.

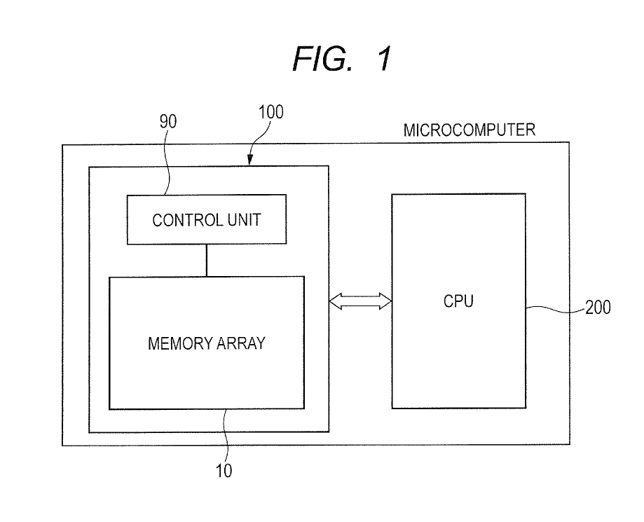

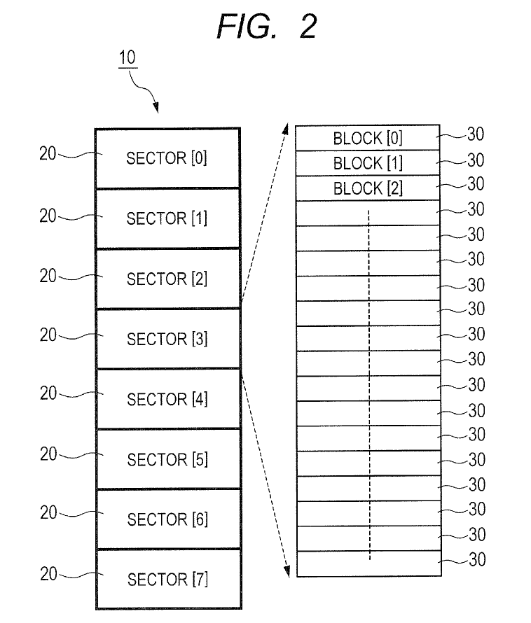

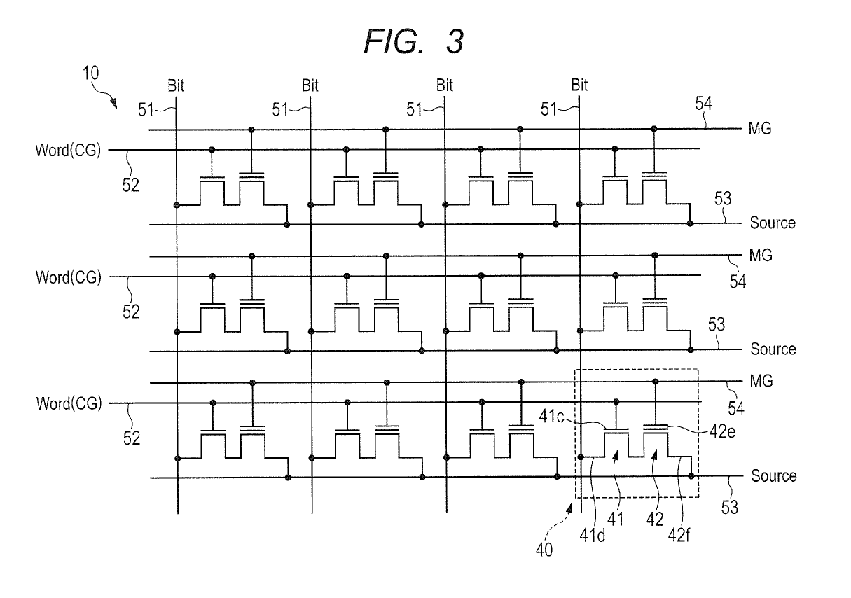

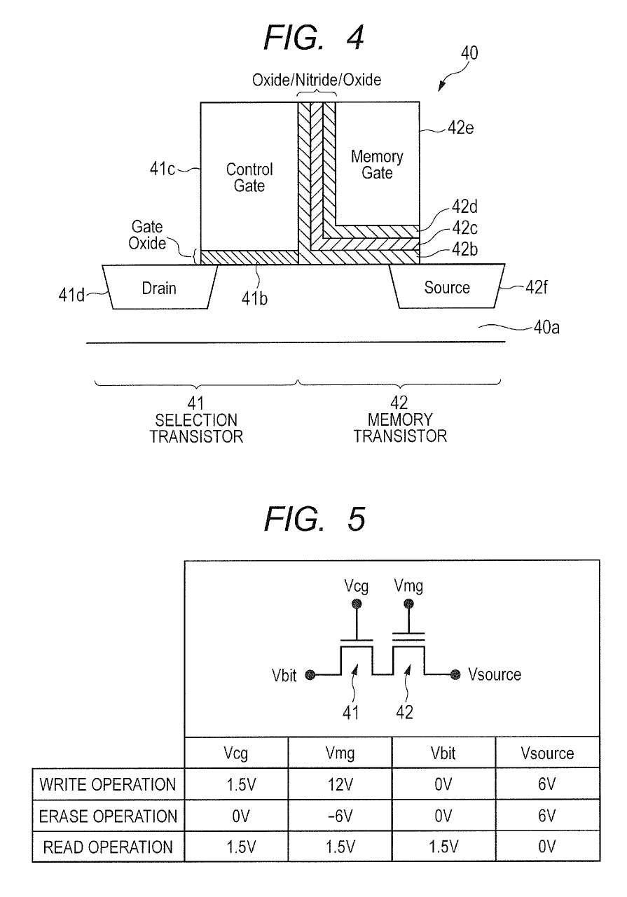

FIG. 1 is a block diagram showing an example of a configuration of a flash memory according to a first embodiment of the present invention. FIG. 2 is a diagram showing an example of a configuration of a memory array according to the first embodiment of the present invention. FIG. 3 is a diagram showing an example of the memory array according to the first embodiment of the present invention. FIG. 4 is a diagram schematically showing a cross-sectional structure of a memory cell according to the first embodiment of the present invention.

As shown in FIG. 1, a flash macro (flash memory) 100 is coupled with a CPU (Central Processing Unit) 200 in a microcomputer and stores data handled by the CPU 200. As shown in FIG. 1, the flash macro 100 includes a memory array 10 and a control unit 90. The memory array 10 and the control unit 90 are coupled to each other and various controls related to input/output of information are performed between the memory array 10 and the control unit 90. For example, the control unit 90 outputs information to the memory array 10, performs rewriting in which the outputted information is coded by the memory array 10, and causes the memory array 10 to store the information. Further, the control unit 90 performs a read operation that reads information stored in the memory array 10 and receives an input of the read information. Further, the control unit 90 performs an erase operation that erases information stored in the memory array 10.

The flash macro 100 includes a peripheral circuit and the like not shown in FIG. 1 in addition to the components described above. The control unit 90 issues operation instructions to the peripheral circuit and the like not shown in FIG. 1 to perform operations such as rewriting, reading, and erasing of the information.

As shown in FIG. 2, the memory array 10 includes a plurality of sectors 20 (for example, sectors [0] to [7]). As shown in FIG. 2, each of the sectors 20 includes a plurality of blocks 30 (for example, blocks [0], [1], [2], and so on.) Each of the block 30 includes a plurality of memory cells 40 shown in FIG. 3. Therefore, the sector 20 also includes a plurality of memory cells 40 shown in FIG. 3. The erase operation is performed on the sector 20 that is defined as an erase unit. In other words, the erase operation is performed on all the memory cells in the sector 20 at the same time.

For example, as shown in FIG. 3, the memory cell 40 is arranged along a bit line 51 and a word line 52. Specifically, the memory cell 40 is arranged corresponding to each position where the bit line 51 and the word line 52 cross each other. In this manner, the memory cells 40 are arranged in a matrix shape along the bit line 51 and the word line 52.

As shown in FIGS. 3 and 4, the memory cell 40 includes a selection transistor 41 and a memory transistor 42. The selection transistor 41 includes, for example, a MOSFET (metal-oxide-semiconductor field-effect transistor). Specifically, as shown in FIG. 4, the selection transistor 41 has a structure in which a gate oxide film (oxide) 41b and a control gate (metal) are laminated over a semiconductor substrate (semiconductor) 40a.

The memory transistor 42 includes, for example, a MONOS (metal-oxide-nitride-oxide-silicon) type transistor. Specifically, as shown in FIG. 4, in the memory transistor 42, an oxide film (oxide) 42b, a nitride film (nitride) 42c, an oxide film (oxide) 42d, and a memory gate (metal) 42e are laminated over the semiconductor substrate (semiconductor) 40a in a region near a source 42f. Further, in a region near the center between the source 42f and the drain 41d, the oxide film (oxide) 42b, the nitride film (nitride) 42c, and the oxide film (oxide) 42d extend vertically upward so as to separate the control gate 41c and the memory gate 42e from each other. In this manner, the memory cell 40 of the present embodiment has a split-gate type MONOS structure having the control gate 41c and the memory gate 42e. The nitride film 42c is sandwiched between the oxide films 42b and 42d that are insulating films and becomes an electrically insulated charge trapping layer. In other words, the memory cell 40 is formed by a charge trapping type memory method.

As shown in FIG. 3, the drain 41d of the selection transistor 41 is coupled with the bit line 51. As shown in FIG. 3, the control gate 41c of the selection transistor 41 is coupled with the word line 52. As shown in FIG. 3, the source 42f of the memory transistor 42 is coupled with the source line 53. As shown in FIG. 3, the memory gate 42e of the memory transistor 42 is coupled with the memory gate line 54.

FIG. 5 is a diagram showing an example of a voltage applied to the memory cell according to the first embodiment of the present invention. FIG. 5 shows voltages respectively applied to the control gate 41c, the memory gate 42e, the bit line 51 (the drain 41d of the selection transistor 41), and the source line 53 (the source 42f of the memory transistor 42) in each of the write operation, the erase operation, and the read operation. According to FIG. 5, during the write operation, for example, a voltage of 1.5 V is applied to the control gate 41c, a voltage of 12 V is applied to the memory gate 42e, a voltage of 0 V is applied to the bit line 51, and a voltage of 6 V is applied to the source line 53. During the write operation, highly efficient hot electrons (electrons) are injected into the nitride film 42c by, for example, a method called Source Side Injection (SSI). The memory cell 40 on which the write operation is performed holds information “0”.

During the erase operation, for example, a voltage of 0 V is applied to the control gate 41c, a voltage of −6 V is applied to the memory gate 42e, a voltage of 0 V is applied to the bit line 51, and a voltage of 6 V is applied to the source line 53. The erase operations are performed on all the memory cells 40 in the sector 20 at the same time. During the erase operation, hot holes (holes) are injected into the nitride film 42c by, for example, a method called Band-to-band Tunneling Hot Hole (BTBTHH). The memory cell 40 on which the erase operation is performed holds information “1”.

During the read operation, for example, a voltage of 1.5 V is applied to the control gate 41c, a voltage of 1.5 V is applied to the memory gate 42e, a voltage of 1.5 V is applied to the bit line 51, and a voltage of 0 V is applied to the source line 53.

In the flash macro 100, a threshold voltage of the memory transistor 42 is changed by injecting charges into the nitride film 42c. For example, the threshold voltage of the memory transistor 42 in a state in which electrons are injected into the nitride film 42c is higher than the threshold voltage in a neutral state in which there are neither electrons nor holes in the nitride film 42c, for example, as shown in FIG. 15. On the other hand, the threshold voltage of the memory transistor 42 in a state in which holes are injected into the nitride film 42c is higher than the threshold voltage in the neutral state in which there are neither electrons nor holes in the nitride film 42c, for example, as shown in FIG. 15.

### [Method of Using Flash Memory]

Next, an example of a method of using the flash memory according to the present embodiment will be described. Regarding a method of using the flash macro 100, for example, there is a method in which information coding is performed on the memory cells 40 in the memory array 10 at the same time (arbitrary erased cells are changed to written cells) and then the memory cells 40 are erased at the same time and thereafter the coding is performed again. However, here, a case will be described in which the flash macro 100 is used by using a method called an EEPROM (electrically erasable and programmable read-only memory) emulation of a flash memory. The EEPROM emulation is a method in which when small capacity information is rewritten many times, the memory array 10 is used by collectively erasing a certain sector 20 and thereafter performing rewriting on a small capacity block 30, sequentially switching the block 30 for each use of the block 30, and sequentially switching to the next sector (the other sector) 20 when all the blocks 30 in the certain sector (one sector) 20 are used.

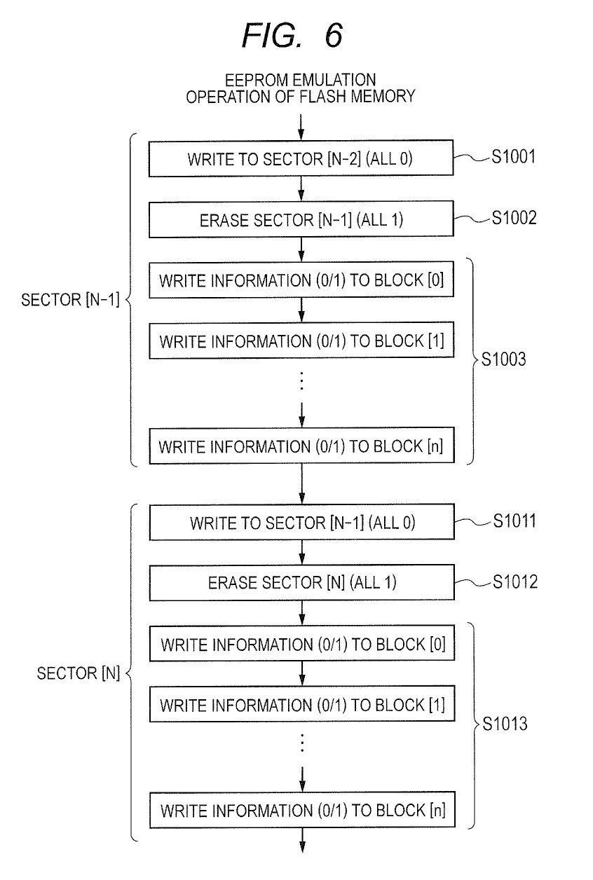

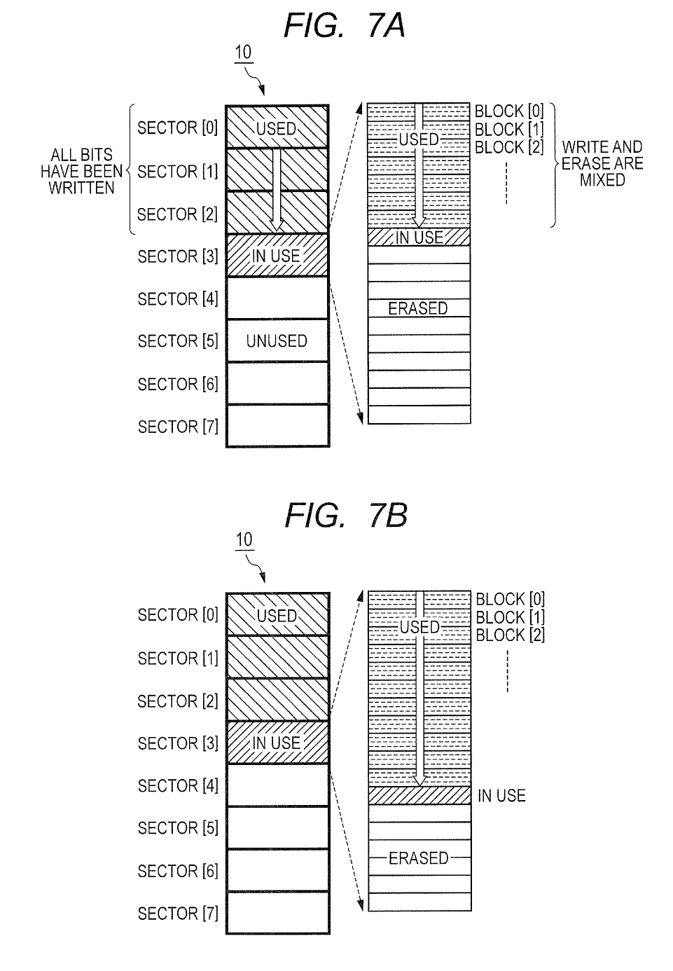

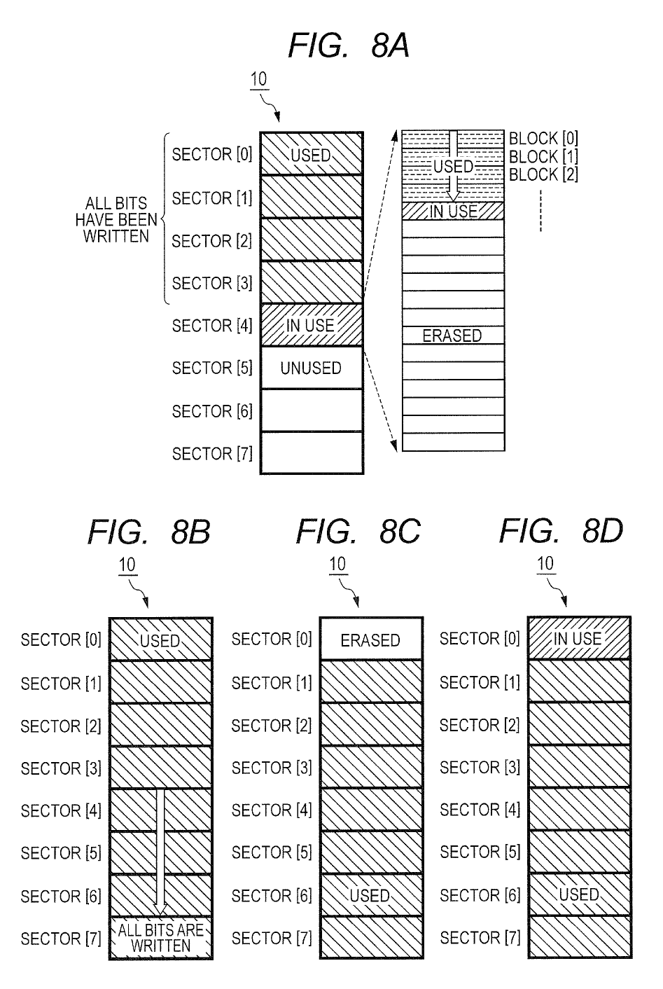

FIG. 6 is a flowchart showing an example of a method of using the flash memory according to the first embodiment of the present invention. FIG. 6 illustrates a case in which the (N−1)th sector 20 is used and thereafter the Nth sector 20 is used. FIGS. 7 and 8 are diagrams showing a usage state of the memory array according to the first embodiment of the present invention.

In step S1001, when the (N−1)th sector 20 (for example, the sector [3]) is used, the write operation is performed on all the memory cells 40 in the (N−2)th sector 20 (for example, the sector [2]) which has been used. Specifically, the control unit 90 outputs a write signal for performing the write operation on all the memory cells 40 in the (N−2)th sector 20. In the memory array 10, the write operation is performed based on the inputted write signal. Specifically, the voltages related to the write operation in FIG. 5 are applied to terminals of all the memory cells 40 in the (N−2)th sector 20. When the write operation is performed, information held by all the memory cells 40 in the (N−2)th sector 20 becomes “0” (ALL 0). Then, the process proceeds to step S1002.

In step S1002, the erase operation is performed on all the memory cells 40 in the (N−1)th sector 20 to be used from now on. Specifically, the control unit 90 outputs an erase signal for performing the erase operation on all the memory cells 40 in the (N−1)th sector 20. In the memory array 10, the erase operation is performed based on the inputted erase signal. Specifically, the voltages related to the erase operation in FIG. 5 are applied to all the memory cells 40 in the (N−1)th sector 20. When the erase operation is performed, information held by all the memory cells 40 in the (N−1)th sector 20 becomes “1” (ALL 1). Then, the process proceeds to step S1003.

In step S1003, the rewriting is performed and information is coded while sequentially using the blocks 30 in the (N−1)th sector 20. Specifically, for example, as shown in FIGS. 7A and 7B, each time desired information is coded in the block 30, the rewriting is performed while sequentially switching the block 30 to be used. Specifically, first, the control unit 90 outputs a write signal to code desired information in a first block 30 (for example, block [0]). In the memory array 10, the rewriting is performed on the first block 30 of the (N−1)th sector 20 based on the inputted write signal. For example, the voltages related to the write operation in FIG. 5 are applied to the memory cells 40 to which information of “0” is written. Information held by the other memory cells 40 is still “1”. Therefore, in the block 30 that has been used, the memory cells 40 holding the information “0” and the memory cells 40 holding the information “1” coexist.

When the write operation to the first block 30 of the (N−1)th sector 20 has been performed, the write operation to the next block 30 is performed. By sequentially repeating such an operation, the write operation is performed on all the blocks 30 in the (N−1)th sector 20. When all the blocks in the (N−1)th sector 20 have been sequentially used, the process proceeds to step S1011.

In step S1011, when the Nth sector 20 (for example, sector [4]) is used, the write operation is performed on all the memory cells 40 in the (N−1)th sector 20 which has been used (ALL 0). The specific operation is the same as that of step S1001 described above, so that detailed description will be omitted. Then, the process proceeds to step S1012.

In step S1012, the erase operation is performed on all the memory cells 40 in the Nth sector 20 (ALL 1). The specific operation is the same as that of step S1002 described above, so that detailed description will be omitted. Then, the process proceeds to step S1013.

In step S1013, as shown in FIG. 8A, the rewriting is performed and the information is coded while sequentially using the blocks 30 in the Nth sector 20. The specific operation is the same as that of step S1003 described above, so that detailed description will be omitted.

These operations are sequentially performed and the sectors 20 from the first sector (for example, the sector [0]) to the last sector (for example, the sector [7]) are sequentially used. When the first sector 20 is used again, as shown in FIG. 8B, the write operation is performed on all the memory cells 40 in the last sector 20 that has been used. Then, as shown in FIGS. 8C and 8D, the erase operation is performed on all the memory cells 40 in the first sector 20 (for example, the sector [0]) and thereafter the first sector 20 is used again.

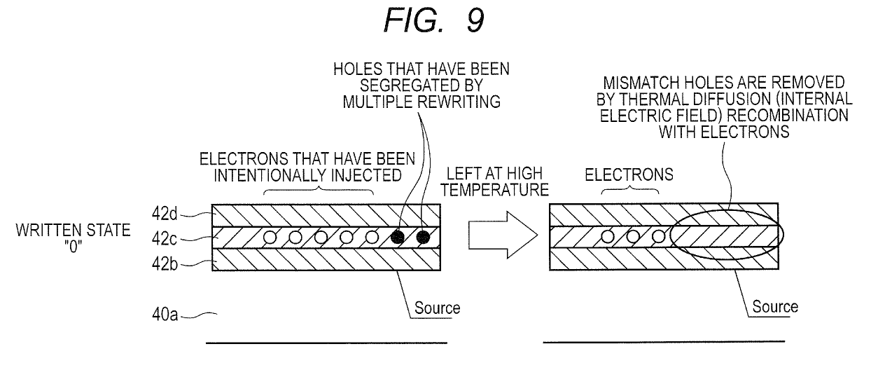

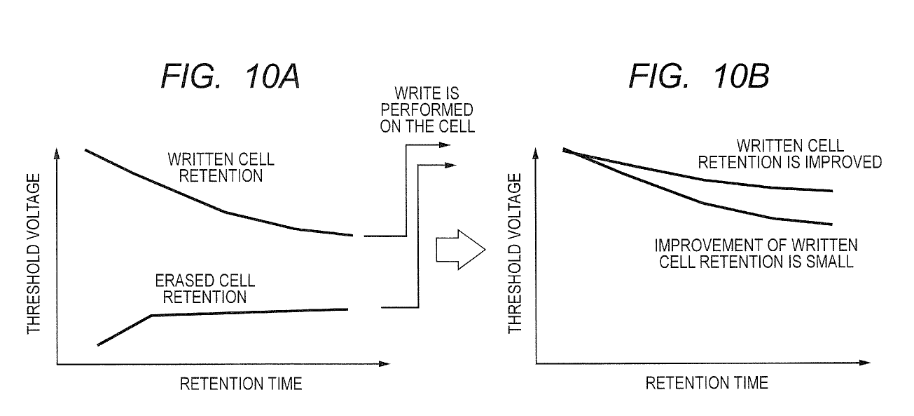

Here, behavior of charges in the sector 20 that has been used will be described. FIG. 9 is a diagram schematically showing a process in which mismatch charges disappear in the first embodiment of the present invention. FIGS. 10A and 10B are diagrams schematically showing fluctuations of threshold voltages in the memory cell 40 according to the first embodiment of the present invention.

When the position and the amount of electrons injected by one write operation are not the same as the position and the amount of holes injected by one erase operation, as shown in FIG. 9, holes are gradually accumulated as mismatch charges in the nitride film 42c near the source 42f of the memory transistor 42. Such a condition is noticeable when an intermediate threshold voltage, a write threshold voltage, and an erase threshold voltage of the memory transistor 42 have a relationship of |the write threshold voltage−the intermediate threshold voltage|<|the intermediate threshold voltage−the erase threshold voltage| and the amount of injected charges (holes) required for one erase operation is greater than the amount of injected charges (electrons) required for one write operation.

In the nitride film 42c of the memory cell 40 that holds information of “0”, as shown in FIG. 9, the electrons injected by the write operation coexist with the holes that are mismatch charges. In this state, for example, if the nitride film 42c is left as it is in a high temperature state or for a long time, as shown in FIG. 9, these charges are gradually recombined and eliminated by an internal electric field between electrons and holes and thermal diffusion. Then, as shown in FIG. 10A, a large fluctuation (drop) of the threshold voltage occurs in the memory cell 40. However, such mismatch charges (holes) disappear by the time when the sector 20 is used again, so that when the sector 20 is used again, as shown in FIG. 10B, the fluctuation of the threshold voltage in the memory cell 40 on which the write operation is performed is suppressed and the retention characteristics are improved. For example, if the time until the sector 20 is used again is short, the improvement of the retention characteristics is small, and if the time until the sector 20 is used again is long, the retention characteristics are further improved.

According to the present embodiment, when one sector 20 has been used and thereafter another sector 20 is used, the write operation is performed on all the memory cells 40 of the sector 20 that has been used.

According to this configuration, in the memory cells 40 of the sector 20 that has been used, the holes that are mismatch charges are recombined with the electrons, and the holes disappear by the time when the sector 20 is used next time. Thereby, even if the write operation is performed when the sector 20 is used next time, the recombination of holes and electrons is suppressed, so that the fluctuation of threshold voltage is suppressed and the retention characteristics after the rewriting are improved.

Further, according to the present embodiment, all the blocks 30 of one sector 20 are sequentially used and thereafter another sector is used.

According to this configuration, a load applied to each block 30 in the sector 20 is distributed, so that it is possible to lengthen the device life of the flash macro 100. Thereby, it is also possible to improve an apparent rewriting resistance.

Further, according to the present embodiment, the first sector 20 is used, thereafter all the sectors 20 are sequentially used, and thereafter the first sector 20 is used again.

According to this configuration, all the sectors 20 included in the memory array 10 are used, so that a time until a sector 20 that has been used is used again is secured. Thereby, the recombination of the holes that are mismatch charges and the electrons is facilitated and the retention characteristics after the rewriting are improved.

Further, according to this configuration, a load applied to each sector 20 included in the memory array 10 is distributed, so that it is possible to lengthen the product life of the flash macro 100. Thereby, it is also possible to improve the apparent rewriting resistance.

Further, according to the present embodiment, after all the blocks 30 in a certain sector 20 are sequentially used, another sector is used, and after all the other sectors 20 are sequentially used, the certain sector 20 is used again.

According to this configuration, all the blocks in the memory array 10 are sequentially used, so that a time until a sector 20 that has been used is used again is secured. Thereby, the recombination of the holes that are mismatch charges and the electrons is facilitated and the retention characteristics after the rewriting are improved.

Further, according to the present embodiment, the memory cell 40 has the MONOS type memory transistor 42.

According to this configuration, in the nitride film 42c of the memory transistor 42, the mismatch charges (holes) segregated in a region facing the source 42f and the electrons injected by the write operation are recombined and the mismatch charges disappear. Thereby, even if the write operation is performed when the sector 20 is used again, the recombination of the holes and the electrons is suppressed, so that the fluctuation of threshold voltage is suppressed and the retention characteristics are improved.

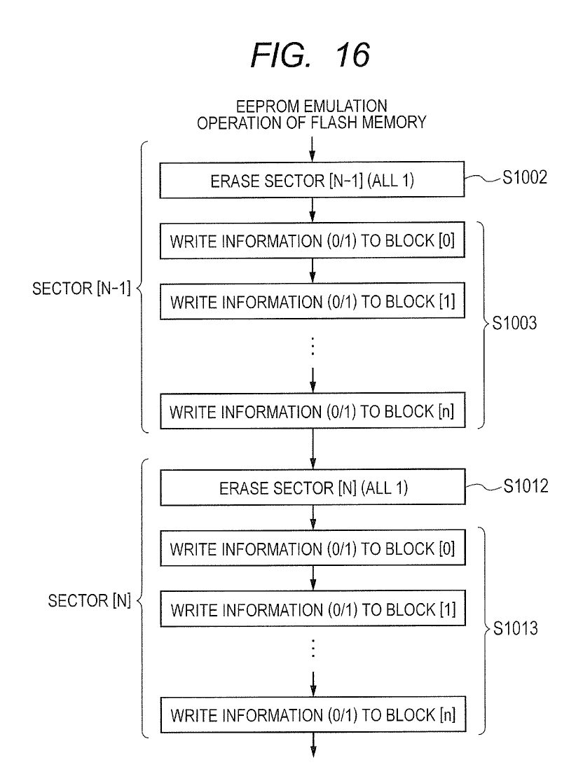

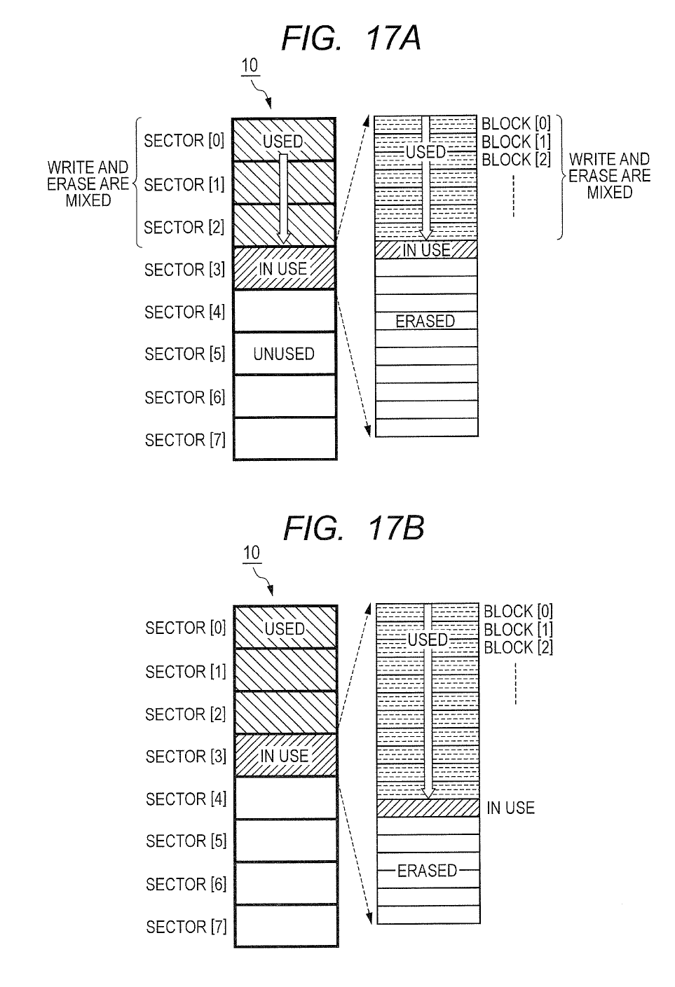

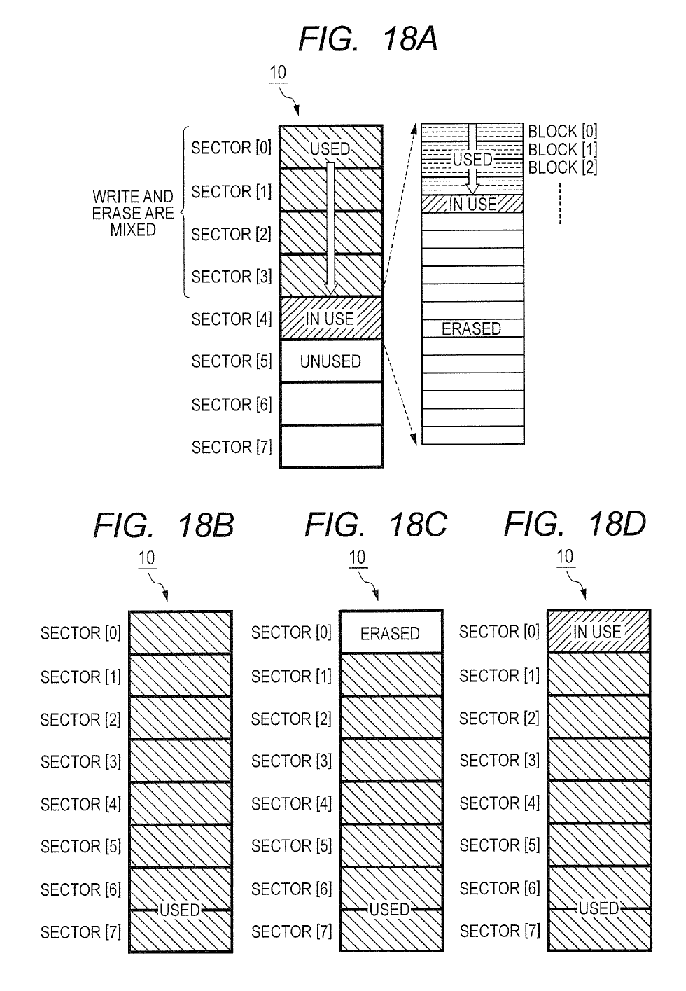

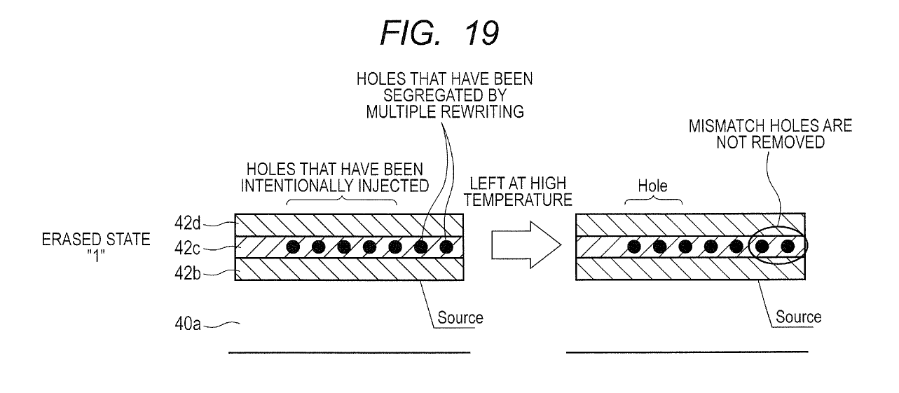

Here, an EEPROM emulation using a related art flash memory will be described. FIG. 16 is a flowchart showing an example of a method of using the related art flash memory. FIGS. 17 and 18 are diagrams showing a usage state of a memory array in the related art flash memory. FIG. 19 is a diagram schematically showing mismatch charges in the related art flash memory.

In the related art flash memory, as shown in FIG. 16, the operations corresponding to steps S1001 and S1011 in FIG. 6 are not performed. Specifically, the write operation is not performed on the sector 20 that has been used and a state of the memory cells in the sector 20 in which information is coded is maintained until the sector 20 is used again. Therefore, in the used sectors 20 shown in FIGS. 17 and 18, the memory cells 40 whose data is “0” and which is in a written state and the memory cells 40 whose data is “1” and which is in an erased state coexist. In this state, the sectors 20 wait until they are used again. However, the sectors 20 are exposed to high temperature, so that there is a chance that the mismatch charges (holes) in the nitride film 42c are reduced. However, the effect of the above varies depending on the memory cells 40, so that a stable improvement of the retention characteristics cannot be expected.

For example, in the memory cell 40 that holds information “0”, for example, as shown in FIG. 9, the electrons injected in steps S1003 and S1013 recombine with the holes that are mismatch charges. Therefore, in such a memory cell 40, the retention characteristics are improved when the memory cell 40 is used next time. On the other hand, for example, in the memory cell 40 that holds information “1”, as shown in FIG. 19, the holes injected by the erase operations in steps S1002 and S1012 in FIG. 16 coexist with the holes that are mismatch charges. In this case, the recombination of the electrons and the mismatch charges does not occur, so that the retention characteristics in the memory cell 40 that is in an erased state are not improved.

### Second Embodiment

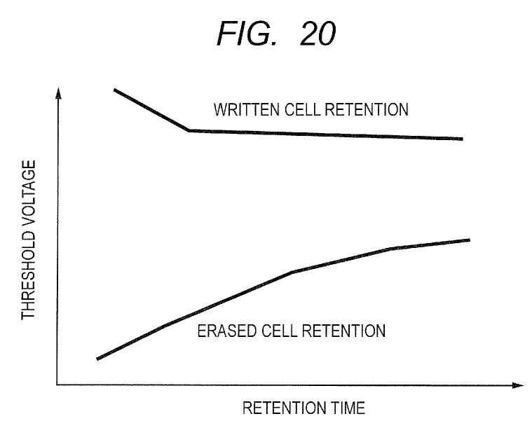

In the present embodiment, a case will be described in which the mismatch charges are electrons. FIG. 20 is a diagram showing retention characteristics in a flash memory studied by the inventors. In a memory cell (an erased cell) in which a write operation is not performed during rewriting, electrons which are mismatch charges coexist with holes which are injected by an erase operation. Therefore, as shown in FIG. 20, a threshold voltage in the memory cell fluctuates (rises) largely. Thus, in the erased cell, the retention characteristics degrade. On the other hand, in a memory cell (a written cell) in which the write operation is performed during rewriting, electrons which are mismatch charges coexist with electrons which are injected by the write operation, and holes and the electrons rarely recombine with each other, so that the threshold voltage in the memory cell hardly fluctuates. Therefore, in the written cell, the degradation of the retention characteristics is suppressed. That is, when the mismatch charges are electrons, a fluctuation range of the threshold voltage in the memory cell on which the erase operation is performed is greater than a fluctuation range of the threshold voltage in the memory cell on which the write operation is performed.

A configuration of the flash memory according to the present embodiment is the same as that of the first embodiment described above, so that detailed description is omitted here.

Next, an example of a method of using the flash memory according to the present embodiment will be described. Here too, a case will be described in which the flash macro 100 is used by using a method called an EEPROM emulation of a flash memory.

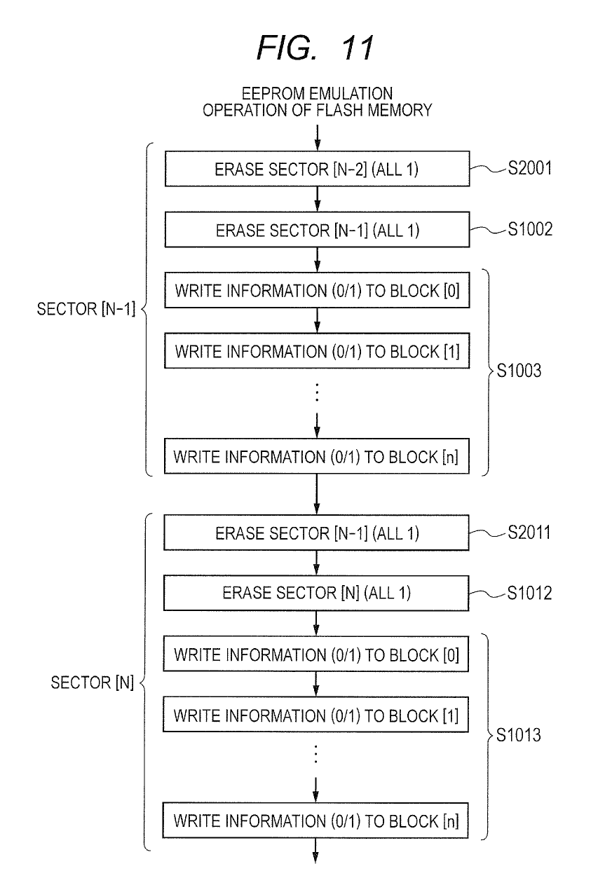

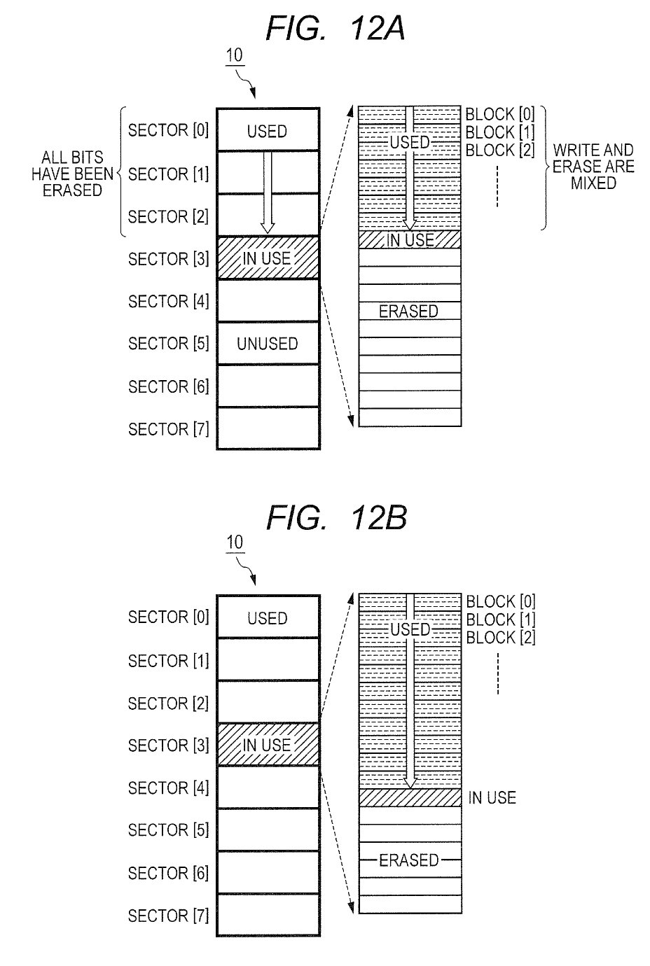

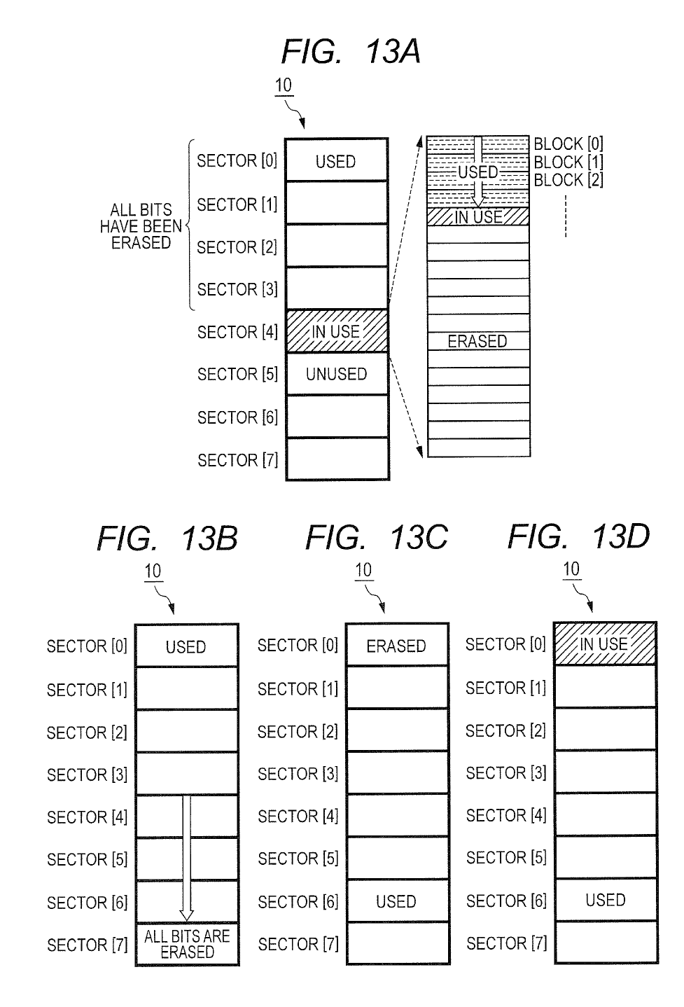

FIG. 11 is a flowchart showing an example of the method of using the flash memory according to the second embodiment of the present invention. FIG. 11 illustrates a case in which the (N−1)th sector 20 is used and thereafter the Nth sector 20 is used. FIGS. 12 and 13 are diagrams showing a usage state of a memory array according to the second embodiment of the present invention.

In step S2001, when the (N−1)th sector 20 (for example, the sector [3]) is used, the erase operation is performed on all the memory cells 40 in the (N−2)th sector 20 (for example, the sector [2]) which has been used. Specifically, the control unit 90 outputs an erase signal for performing the erase operation on all the memory cells 40 in the (N−2)th sector 20. In the memory array 10, the erase operation is performed based on the inputted erase signal. Specifically, the voltages related to the erase operation in FIG. 5 are applied to terminals of all the memory cells 40 in the (N−2)th sector 20. When the erase operation is performed, data of all the memory cells 40 in the (N−2)th sector 20 become “1” (ALL 1). Then, the process proceeds to step S1002.

In step S1002, the erase operation is performed on all the memory cells 40 in the (N−1)th sector 20 to be used from now on. Step S1002 has already been described in the first embodiment, so that detailed description is omitted here.

In step S1003, information is coded by sequentially using the blocks 30 in the (N−1)th sector 20. Specifically, for example, as shown in FIGS. 12A and 12B, each time desired information is coded in the block 30, the rewriting is performed while sequentially switching the block 30 to be used. Step S1003 has already been described in the first embodiment, so that detailed description is omitted here. When the operation of step S1003 is completed, the process proceeds to step S2011.

In step S2011, when the Nth sector 20 is used, the erase operation is performed on all the memory cells 40 (ALL 1) in the (N−1)th sector 20 which has been used. The specific operation is the same as that of step S2001 described above, so that detailed description will be omitted. Then, the process proceeds to step S1012.

In step S1012, the erase operation is performed on all the memory cells 40 in the Nth sector 20 (ALL 1). The specific operation is the same as that of step S1002 described above, so that detailed description will be omitted. Then, the process proceeds to step S1013.

In step S1013, as shown in FIG. 13A, data is written by sequentially using the blocks 30 of the Nth sector 20. The specific operation is the same as that of step S1003 described above, so that detailed description will be omitted.

These operations are sequentially performed and the sectors 20 from the first sector (for example, the sector [0]) to the last sector 20 (for example, the sector [7]) are sequentially used. When the first sector 20 is used again, as shown in FIG. 13B, the erase operation is performed on all the memory cells 40 in the last sector 20 that has been used. Then, as shown in FIGS. 13C and 13D, the erase operation is performed on all the memory cells 40 in the first sector 20 (for example, the sector [0]) and thereafter the first sector 20 is used again.

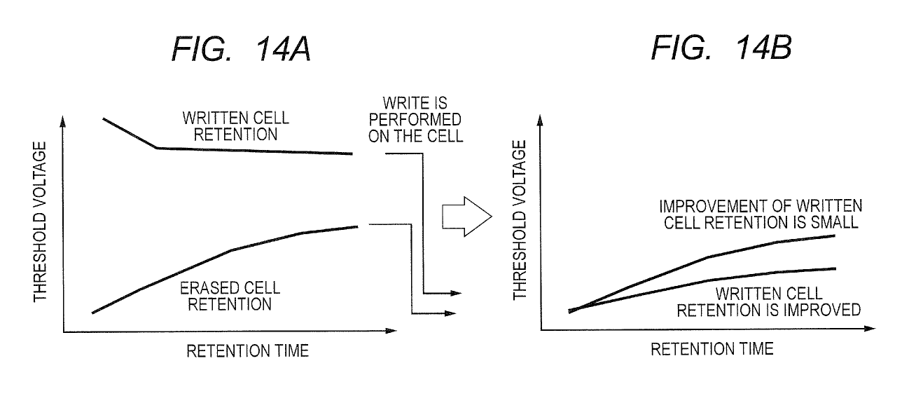

Here, behavior of charges in the sector 20 that has been used will be described. FIGS. 14A and 14B are diagrams schematically showing a process in which the mismatch charges disappear in the second embodiment of the present invention. FIGS. 14A and 14 B are diagrams schematically showing fluctuations of threshold voltages in a memory cell according to the second embodiment of the present invention.

In the nitride film 42c of the memory cell 40 that holds information of “1”, the holes injected by the erase operation coexist with the electrons that are mismatch charges. In this state, for example, if the nitride film 42c is left as it is in a high temperature state or for a long time, these charges are gradually recombined and eliminated by an internal electric field between electrons and holes and thermal diffusion. Then, as shown in FIG. 14A, a large fluctuation (rise) of the threshold voltage occurs in the memory cell 40. However, such mismatch charges (electrons) disappear by the time when the sector 20 is used again, so that when the sector 20 is used again, as shown in FIG. 14B, the fluctuation of the threshold voltage in the memory cell 40 on which the erase operation is performed is suppressed and the retention characteristics are improved. For example, if the time until the sector 20 is used again is short, the improvement of the retention characteristics is small, and if the time until the sector 20 is used again is long, the retention characteristics are further improved.

According to the present embodiment, when one sector 20 has been used and thereafter another sector 20 is used, the erase operation is performed on all the memory cells 40 of the sector 20 that has been used.

According to this configuration, in the memory cells 40 of the sector 20 that has been used, the electrons that are mismatch charges are recombined with the holes, and the electrons disappear by the time when the sector 20 is used again. Thereby, even if the erase operation is performed when the sector 20 is used again, the recombination of the holes and the electrons is suppressed, so that the fluctuation of threshold voltage is suppressed and the retention characteristics after the rewriting are improved.

Further, according to the present embodiment, all the blocks 30 of one sector 20 are sequentially used and thereafter another sector 20 is used.

According to this configuration, a load applied to each block 30 in the sector 20 is distributed, so that it is possible to lengthen the device life of the flash macro 100. Thereby, it is also possible to improve an apparent rewriting resistance.

Further, according to the present embodiment, the first sector 20 is used, thereafter all the sectors 20 are sequentially used, and thereafter the first sector 20 is used again.

According to this configuration, all the sectors 20 included in the memory array 10 are used, so that a time until a sector 20 that has been used is used again is secured. Thereby, the recombination of the holes that are mismatch charges and the electrons is facilitated and the retention characteristics after the rewriting are improved.

Further, according to this configuration, a load applied to each sector 20 included in the memory array 10 is distributed, so that it is possible to lengthen the product life of the flash macro 100. Thereby, it is also possible to improve the apparent rewriting resistance.

Further, according to the present embodiment, after all the blocks 30 in a certain sector 20 are sequentially used, another sector is used, and after all the other sectors 20 are sequentially used, the certain sector 20 is used again.

According to this configuration, all the blocks in the memory array 10 are sequentially used, so that a time until a sector 20 that has been used is used again is secured. Thereby, the recombination of the holes that are mismatch charges and the electrons is facilitated and the retention characteristics after the rewriting are improved.

Further, according to the present embodiment, the memory cell 40 has the MONOS type memory transistor 42.

According to this configuration, in the nitride film 42c of the memory transistor 42, the segregated mismatch charges (electrons) and the holes injected by the erase operation are recombined and the mismatch charges disappear. Thereby, even if the erase operation is performed when the sector 20 is used again, the recombination of the holes and the electrons is suppressed, so that the fluctuation of threshold voltage is suppressed and the retention characteristics after the rewriting are improved.

### Other Embodiments

In the embodiments described above, the memory cell 40 is formed by a MONOS memory method having a MONOS structure. However, the memory cell 40 is not limited to such a configuration. For example, the memory cell may be formed by another high dielectric constant insulating film instead of a silicon nitride film (for example, a hafnium oxide film or the like) or a charge trap method such as a silicon dot (an insulating film in which silicon particulates are dispersed). Also in this case, recombination of mismatch charges segregated in a charge trap film and charges injected by a write operation or an erase operation is promoted and the retention characteristics after rewriting are improved.

In the embodiments described above, a case is described in which all the blocks 30 in one sector 20 are used and thereafter another sector 20 is used. However, the present invention is not limited to such embodiments. For example, when a plurality of blocks 30 included in a plurality of sectors 20 are used, instead of using remaining blocks 30 in a sector 20 that is currently being used, blocks 30 in another sector 20 may be used from the first block 30 of the sector 20.

By doing so, it is not necessary to store information of the plurality of sectors, so that the erase operation on a sector 20 that has been used is performed in a short time. Thereby, a time until the sector 20 that has been used is used next time is secured, so that recombination of mismatch charges and injected charges is promoted and the retention characteristics after rewriting are improved.

Further, for example, when information greater than the capacity of one sector 20 is stored, blocks 30 in another sector 20 may be used from the first block 30 of the sector 20. Thereby, the erase operation on the sector 20 that has been used most recently is performed in a short time. Thereby, a time until the sector 20 that has been used is used next time is secured, so that recombination of mismatch charges and injected charges is promoted and the retention characteristics after rewriting are improved.

Further, it is possible that the flash macro 100 according to the embodiments described above is not mounted in a microcomputer but forms a control system along with another semiconductor device as an independent semiconductor device. According to this configuration, a flash memory whose retention characteristics are improved is used, so that a control system whose reliability is improved is provided.

Further, a microcomputer in which the flash memory mentioned above is mounted may be mounted in a vehicle. According to this configuration, a microcomputer whose reliability is improved is used, so that a vehicle whose reliability is improved is provided. A flash memory mounted close to an engine room or the like becomes a high temperature state, so that recombination of mismatch charges and injected charges is promoted, and thereby the retention characteristics are improved.

While the invention made by the inventors has been specifically described based on the embodiments, it is needless to say that the present invention is not limited to the embodiments that have been described, but can be variously changed without departing from the scope of the invention.

What is claimed is:

1. A flash memory comprising:
a plurality of sectors each of which includes a plurality of memory cells,
wherein before a sector collective erase operation before a data write operation on one of the sectors, the write operation is performed on all the memory cells of the one of the sectors.

2. A flash memory comprising:
a plurality of sectors each of which includes a plurality of memory cells,
wherein before a sector collective erase operation before a data write operation on one of the sectors, the erase operation is performed on all the memory cells of the one of the sectors and no write operation is performed on the one of the sectors in a period from when the erase operation is started to when the sector collective erase operation is completed.

3. The flash memory according to claim 1,
wherein the sector includes a plurality of blocks, and
wherein after all the blocks of the one of the sectors are sequentially used, another of the sectors is used.

4. The flash memory according to claim 1,
wherein after all the other sectors are sequentially used, the one of the sectors is used again.

5. The flash memory according to claim 1,
wherein the sector includes a plurality of blocks, and
wherein after all the blocks of the one of the sectors are sequentially used, another of the sectors is used, and after all the other sectors are sequentially used, the one of the sectors is used again.

6. The flash memory according to claim 1,
wherein the memory cell has a MONOS (metal-oxide-nitride-oxide-silicon) type transistor.

7. The flash memory according to claim 5,
wherein the memory cell is formed by a charge trap method.

8. The flash memory according to claim 2,
wherein the sector includes a plurality of blocks, and
wherein after all the blocks of the one of the sectors are sequentially used, another of the sectors is used.

9. The flash memory according to claim 2,
wherein after all the other sectors are sequentially used, the one of the sectors is used again.

10. The flash memory according to claim 2,
wherein the sector includes a plurality of blocks, and
wherein after all the blocks of the one of the sectors are sequentially used, another of the sectors is used, and after all the other sectors are sequentially used, the one of the sectors is used again.

11. The flash memory according to claim 2,
wherein the memory cell has a MONOS (metal-oxide-nitride-oxide-silicon) type transistor.
